(19) United States
(12) Patent Application Publication
(10) Pub. No.: US 2023/0017232 A1
(43) Pub. Date: Jan. 19, 2023

(54) ELECTRO-STATIC DISCHARGE PROTECTION CIRCUIT AND CHIP

(71) Applicant: CHANGXIN MEMORY TECHNOLOGIES, INC., Hefei City (CN)

(72) Inventor: Qian XU, Hefei City (CN)

(21) Appl. No.: 17/812,745

(22) Filed: Jul. 15, 2022

Related U.S. Application Data
(63) Continuation of application No. PCT/CN2021/120263, filed on Sep. 24, 2021.

(30) Foreign Application Priority Data
Jul. 19, 2021 (CN) 202110812621.X

(51) Int. Cl. H01L 27/02

(52) U.S. Cl. CPC H01L 27/0262

(57) ABSTRACT

Embodiments of the present application provide an electro-static discharge protection circuit and a chip. The electro-static discharge protection circuit includes: a silicon-controlled rectifier, including an anode, a cathode and an electro-static discharge path; a detection unit, connected between the anode and the cathode of the silicon-controlled rectifier, and configured to generate a trigger signal in response to static electricity occurring in a protected chip; and a switching unit, connected to the electro-static discharge path, including an input terminal connected to an output terminal of the detection unit, and configured to turn on the electro-static discharge path based on the trigger signal to discharge an electro-static discharge current.

### CROSS-REFERENCE TO RELATED APPLICATIONS

This is a continuation of International Application No. PCT/CN2021/120263, filed on Sep. 24, 2021, which claims the priority to Chinese Patent Application No. 202110812621.X, filed on Jul. 19, 2021 and titled “Electro-Static Discharge Protection Circuit and Chip”. The entire contents of International Application No. PCT/CN2021/120263 and Chinese Patent Application No. 202110812621.X are incorporated herein by reference.

### TECHNICAL FIELD

The present application relates to the technical field of integrated circuits (ICs), and in particular to an electro-static discharge protection circuit and a chip.

### BACKGROUND

In modern times, the manufacture of semiconductors is becoming more advanced, with shorter trenches and smaller junction depths. As applications of silicides and lightly doped drains (LDDs) expand, there are thinner oxide layers and smaller electro-static discharge (ESD) design windows, which imposes greater challenges for electro-static discharge protection. For an existing electro-static discharge protection circuit, since a resistor-capacitor (RC) circuit is connected to an N-channel metal-oxide semiconductor (NMOS) transistor through an inverter to affect the turn-on speed of the NMOS transistor, an acceleration module is often provided to achieve a faster turn-on speed of the NMOS transistor and a faster trigger speed of the electro-static discharge protection circuit. However, this enlarges the size of the electro-static discharge protection circuit, increases the cost and does not meet use requirements of advanced manufacture on ICs.

### SUMMARY

According to a first aspect, an embodiment of the present application provides an electro-static discharge protection circuit, including:

a silicon-controlled rectifier, including an anode, a cathode and an electro-static discharge path;

a detection unit, connected between the anode and the cathode of the silicon-controlled rectifier, and configured to generate a high level in response to static electricity occurring in a protected chip; and

a switching unit, connected to the electro-static discharge path, including an input terminal connected to an output terminal of the detection unit, and configured to turn on the electro-static discharge path based on the high level to discharge an electro-static discharge current.

According to a second aspect, an embodiment of the present application provides a chip, comprising a protected circuit and the above electro-static discharge protection circuit.

### BRIEF DESCRIPTION OF THE DRAWINGS

FIG. 1 is a schematic structural diagram of an electro-static discharge protection circuit according to related art;

FIG. 2 is a structural block diagram of an electro-static discharge protection circuit according to an embodiment of the present application;

FIG. 3 is an equivalent circuit diagram of an electro-static discharge protection circuit according to an embodiment of the present application;

FIG. 4 is a schematic structural diagram of an electro-static discharge protection circuit according to an embodiment of the present application; and

FIG. 5 is a schematic diagram of an equivalent path of an electro-static discharge trigger path in FIG. 3.

### DETAILED DESCRIPTION

In order to facilitate the understanding of the present application, the present application is described more completely below with reference to the drawings. The embodiments of the represent application are shown in the drawings. However, the present application may be embodied in various forms without being limited to the embodiments described herein. These embodiments are provided in order to make the present application more thorough and comprehensive.

Unless otherwise defined, all technical and scientific terms used herein have the same meaning as commonly understood by those skilled in the technical field of the present application. The terms mentioned herein are merely for the purpose of describing specific embodiments, rather than to limit the present application.

It is understandable that the terms such as “first” and “second” used herein may be used to describe various elements, but these elements are not limited by these terms. Instead, these terms are merely intended to distinguish one element from another. For example, without departing from the scope of the present application, the first resistor may be referred to as the second resistor, and similarly, the second resistor may be referred to as the first resistor. Both the first resistor and the second resistor are resistors, but they are not the same.

It can be understood that “connection” in the following embodiments should be understood as “electrical connection” or “communicative connection” if the connected circuits, modules or units have electrical signal or data transmission between each other.

In this specification, the singular forms of “a”, “an” and “the/this” may also include plural forms, unless clearly indicated otherwise. It should also be understood that the terms such as “including/comprising” and “having” indicate the existence of the stated features, wholes, steps, operations, components, parts or combinations thereof. However, these terms do not exclude the possibility of the existence of one or more other features, wholes, steps, operations, components, parts or combinations thereof. In this specification, the term “and/or” includes any and all combinations of related listed items.

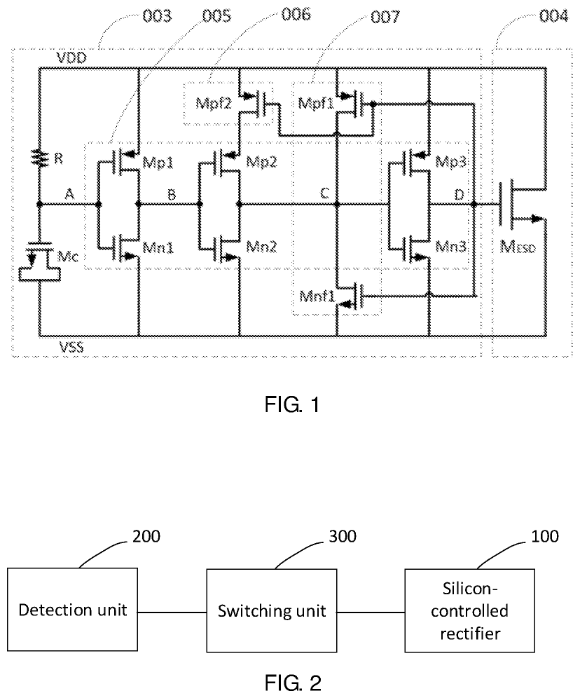

FIG. 1 is a schematic structural diagram of an electro-static discharge protection circuit according to related art. An electro-static discharge protection circuit includes a trigger module and a discharge module. The trigger module 003 includes a three-stage inverter module 005, a P-channel metal-oxide semiconductor (PMOS) feedback module 006, a feedback enhanced trigger module 007, a resistor R and a capacitor Mc of an NMOS transistor. Due to no abrupt change of a gate voltage of the NMOS transistor MESD, an inverter is provided on the input terminal of the NMOS transistor MESD to achieve discharge of the NMOS transistor MESD, which affects the turn-on speed of the NMOS transistor MESD. In view of this, the PMOS feedback module 006 and the feedback enhanced trigger module 007 are provided to achieve a faster turn-on speed of the NMOS transistor MESD and a faster trigger speed of the electro-static discharge protection circuit. However, this enlarges the size of the electro-static discharge protection circuit, increases the cost and do not meet use requirements of advanced manufacture on ICs.

FIG. 2 is a schematic structural diagram of an electro-static discharge protection device according to an embodiment of the present application. An electro-static discharge protection circuit includes an silicon-controlled rectifier 100, a detection unit 200 and a switching unit 300. The silicon-controlled rectifier 100 includes an anode, a cathode and an electro-static discharge path. The detection unit 200 is connected between the anode and the cathode of the silicon-controlled rectifier 100, and configured to generate a high level in response to static electricity occurring in a protected chip (not shown in the figure). The switching unit 300 is connected to the electro-static discharge path, includes an input terminal connected to an output terminal of the detection unit 200, and is configured to turn on the electro-static discharge path based on the high level to discharge an electro-static discharge current.

The protected chip may be a logic chip, an analog chip, a memory chip or the like. The protected chip may specifically be a dynamic random access memory (DRAM) chip when being the memory chip. The silicon-controlled rectifier 100 is located in the protected chip, and connected to a protected circuit in the protected chip. The electro-static discharge protection circuit in the embodiment is implemented with the detection unit 200 and the switching unit 300 and without the acceleration module. The detection unit 200 directly outputs the high level to trigger discharge and turn-on of the switching unit 300 and thus the electro-static discharge path is turned on to discharge the electro-static discharge current. The electro-static discharge protection circuit not only implements electro-static discharge protection for the protected chip, but also has advantages of a simple structure, a small size and a fast trigger speed.

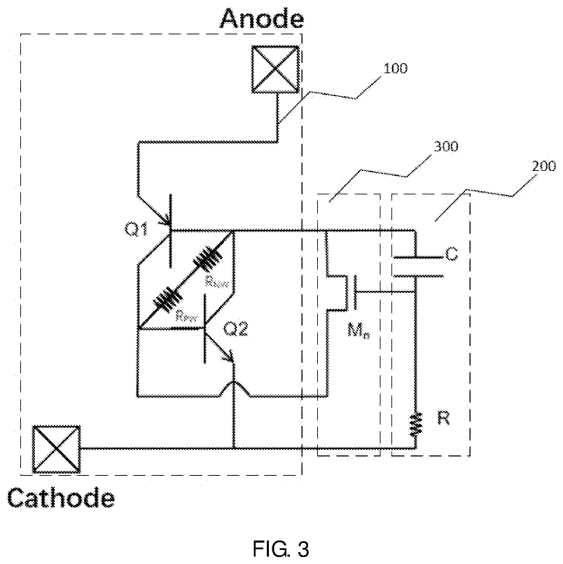

In an embodiment, referring to FIG. 3, the electro-static discharge path includes a first triode Q1, a second triode Q2, a first resistor R_{NW} and a second resistor R_{PW}. In an embodiment, the first triode Q1 includes an emitter serving as the anode of the silicon-controlled rectifier 100, a base connected to one terminal of the first resistor R_{NW} and a collector of the second triode Q2, and a collector connected to one terminal of the second resistor R_{PW} and a base of the second triode Q2. The other terminal of the second resistor R_{PW} is connected to the other terminal of the first resistor R_{NW}. An emitter of the second triode Q2 serves as the cathode of the silicon-controlled rectifier 100.

The first triode Q1 is a PNP triode, and the second triode Q2 is an NPN triode.

In some embodiments of the present application, the switching unit 300 includes one terminal connected to one terminal of the second resistor R_{PW}, the collector of the first triode Q1 and the base of the second triode Q2, and the other terminal connected to one terminal of the first resistor R_{NW}, the base of the first triode Q1 and the collector of the second triode Q2. In response to static electricity occurring in the protected circuit, the anode of the silicon-controlled rectifier outputs a positive pulse through which the first resistor R_{NW} is turned on. The detection unit 200 outputs a high level to the switching unit 300, such that the switching unit 300 discharges and is turned on, the second resistor R_{PW} is turned, and the potential on the base of the second triode Q2 is increased. Therefore, the electro-static discharge path is turned on to discharge an electro-static discharge current. In addition, the switching unit 300 is connected between the first triode Q1 and the second triode Q2, which lengthens the trigger path, enhances the sustain voltage, and avoids the flickering phenomenon.

In an embodiment, the silicon-controlled rectifier 100 further includes an electro-static discharge trigger path. The electro-static discharge trigger path includes a first diode D1 and a second diode D2. The first diode D1 includes a cathode connected to the cathode of the silicon-controlled rectifier 100, and an anode connected to a cathode of the second diode D2. An anode of the second diode D2 is connected to the anode of the silicon-controlled rectifier 100.

In the embodiment, the electro-static discharge trigger path may be equivalent to a diode string, and the switching unit 300 is serially connected to the electro-static discharge trigger path. In response to static electricity occurring, as the diode string has a low turn-on voltage, the electro-static discharge trigger path is turned on by the switching unit 300 and then the electro-static discharge path is turned on. Consequently, a high current passes through the electro-static discharge path quickly to discharge the static electricity at a small trigger voltage.

In an embodiment, the silicon-controlled rectifier 100 includes: a substrate 110.

A fourth well region 120, a first well region 130 and a second well region 140 are formed in the substrate. A first doped region 131 and a second doped region 132 are formed in the first well region 130. A third doped region 141 and a fourth doped region 142 are formed in the second well region 140. A fifth doped region 111 is further formed in the substrate 110. The second doped region 132 is connected to a cathode and formed into the cathode of the silicon-controlled rectifier 100. The third doped region 141 is connected to an anode and formed into the anode of the silicon-controlled rectifier 100.

The third doped region 141, the second well region 140 and the first well region 130 are equivalent to the first triode Q1. The second doped region 132, the first well region 130 and the second well region 140 are equivalent to the second triode Q2.

The first doped region 131 and the second doped region 132 are equivalent to the first diode D1. The third doped region 141 and the fourth doped region 142 are equivalent to the second diode D2.

In other embodiments, the silicon-controlled rectifier 100 may further be another semiconductor device capable of implementing the above functions to those skilled in the art.

In an embodiment, a third deep well region 150 is further formed in the substrate 110. The third deep well region 150 is provided on a lower surface of the first well region 130 and a part of a lower surface of each of the fourth well region 120 and the second well region 140. The third deep well region 150 isolates the first well region 130 and the substrate 110 to make coupling noise of the substrate smaller.

In an embodiment, the detection unit 200 includes a third resistor R and a capacitor C. The capacitor C includes one terminal connected to the anode of the silicon-controlled rectifier 100, and the other terminal connected to one terminal of the third resistor R and serving as the output terminal of the detection unit 200. The other terminal of the third resistor R is connected to the cathode of the silicon-controlled rectifier 100.

In the embodiment, the capacitor C includes one terminal connected to the anode of the silicon-controlled rectifier 100, and the other terminal connected to one terminal of the third resistor R and serving as the output terminal of the detection unit 200, and the other terminal of the third resistor R is connected to the cathode of the silicon-controlled rectifier 100. In response to the static electricity occurring in the protected chip, a forward pulse passes through the capacitor C, such that the output terminal of the detection unit 200 is set at a high potential, namely the input terminal of the switching unit 300 may be set at a high potential, and the switching unit 300 may directly discharge and be turned on. Therefore, the electro-static discharge protection circuit can omit the inverter, improve the turn-on speed of the switching unit 300 without the acceleration module, ensure the electro-static discharge protection performance and minimize the size of the electro-static discharge protection circuit.

In an embodiment, the switching unit 300 includes an NMOS transistor Mn.

In an embodiment, the NMOS transistor Mn includes a gate serving as an input terminal and connected to the output terminal of the detection unit 200, a source connected to one terminal of the second resistor R_{PW}, the collector of the first triode Q1 and the base of the second triode Q2, and a drain connected to one terminal of the first resistor R_{NW}, the base of the first triode Q1 and the collector of the second triode Q2. In response to the static electricity occurring in the protected chip, the forward pulse passes through the capacitor C. As the output terminal of the detection unit 200 is set at the high potential, namely the gate of the NMOS transistor Mn is set at the high potential, the NMOS transistor Mn discharges and the first triode Q1 and the second triode Q2 are turned on sequentially. Therefore, the electro-static discharge path is turned on to discharge the electro-static discharge current.

The present application further provides a chip, including a protected circuit and the above electro-static discharge protection circuit. In response to static electricity occurring in the chip, the electro-static discharge protection circuit can discharge the electro-static discharge current to avoid the damage to the protected circuit. Moreover, the electro-static discharge protection circuit has a simple structure, a small size and a faster trigger speed, and meets use requirements of existing advanced manufacture on ICs.

Exemplarily, the electro-static discharge protection circuit is connected between the power terminal and the ground terminal, the power terminal and the signal transmission terminal, and the ground terminal and the signal transmission terminal in the protected circuit. Specifically, the electro-static discharge protection circuit may be connected between the power terminal and the input terminal, the input terminal and the ground terminal, the power terminal and the output terminal, the output terminal and the ground terminal, and the power terminal and the ground terminal. Moreover, according to actual needs, the anode and cathode of the electro-static discharge protection circuit may be reversely connected to discharge a reverse electro-static discharge current. In the embodiment, the reverse connection is proposed with respect to the forward connection. For example, when the anode of the electro-static discharge protection circuit is forwardly connected to the power terminal of the protected circuit and the cathode of the electro-static discharge protection circuit is forwardly connected to the ground terminal of the protected circuit, the anode of the electro-static discharge protection circuit is reversely connected to the ground terminal of the protected circuit and the cathode of the electro-static discharge protection circuit is reversely connected to the power terminal of the protected circuit.

In an embodiment, the chip may be a logic chip, an analog chip, a memory chip or the like.

In an embodiment, the chip may include a DRAM chip.

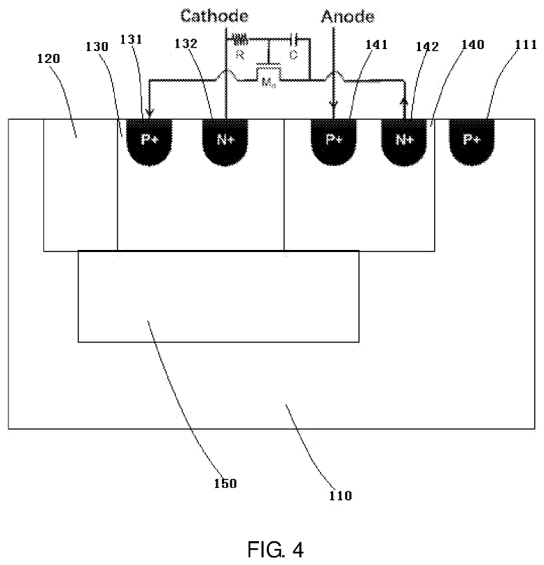

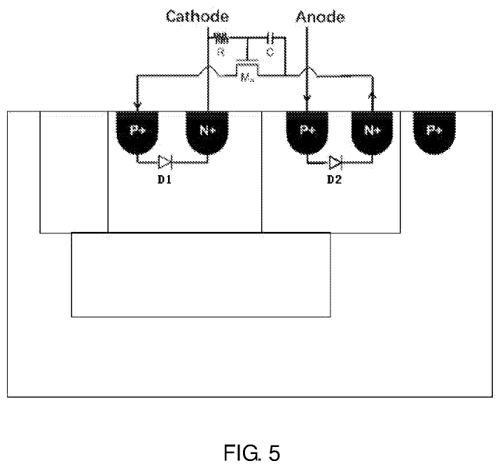

Referring to FIGS. 4 and 5, in an embodiment, the present disclosure further provides a semiconductor device, including:

a substrate, including a first well region 130 with a first conductivity type, such as a P-type well region, and a second well region 140 with a second conductivity type, such as an N-type well region, wherein the first well region 130 is in contact with the second well region 140, and a PN junction is formed on a contact surface.

The first well region 130 is provided with a first doped region 131 with the first conductivity type and a second doped region 132 with the second conductivity type; the second well region 140 is provided with a third doped region 141 with the first conductivity type and a fourth doped region 142 with the second conductivity type; and the second doped region 132 is spaced from the second well region 140, and the third doped region 141 is spaced from the first well region 130.

The substrate is the first conductivity type, including a third deep well region 150 in at least partial contact with the first well region 130, wherein the third deep well region 150 is the second conductivity type, such as an N-type deep well region; the substrate also includes a fourth well region 120 in contact with the first well region 130, wherein the fourth well region 120 is the second conductivity type, such as an N-type well region; and the substrate also includes a fifth doped region 111 arranged outside the first well region 130, the second well region 140, the third deep well region 150 and the fourth well region 120, wherein the fifth doped region 111 is a first conductive type, such as a P-type doped region.

In the semiconductor device provided in the present disclosure, based on the silicon-controlled device, the parasitic formation of a diode can realize the above functions while reducing the area of the electro-static discharge protection circuit.

Referring to FIGS. 3, 4 and 5, the present disclosure also provides an electro-static discharge protection circuit, including the above-mentioned semiconductor device, and a detection unit 200 and a switching unit 300.

The third doped region 141 of the semiconductor device is connected with a first conductive terminal of the protected circuit, such as an anode; and the second doped region 132 of the semiconductor device is connected with a second conductive terminal of the protected circuit, such as a cathode.

The detection unit 200 is coupled between the first conductive terminal and the second conductive terminal of the protected circuit, and is configured to control the switching unit 300 to turn on when the first conductive terminal receives an electrostatic pulse, and to control the switching unit 300 to turn off after a predetermined time.

One terminal of the switching unit 300 is connected with the first doping region 131, and the other terminal is connected with the fourth doping region 142. The switching unit 300 is configured to electrically connect the first doped region 131 with the fourth doped region 142 when it is turned on, and disconnect the first doped region 131 from the fourth doped region 142 when it is turned off.

The detection unit 200 includes a third resistor R and a capacitor C, wherein one terminal of the third resistor R is connected with the second conductive terminal of the protected circuit, the other terminal of the third resistor R is connected with a first terminal of the capacitor C, and a second terminal of the capacitor C is connected with the fourth doped region 142.

The switching unit 300 may be a switching transistor, such as an NMOS transistor Mn, whose gate is connected with the first terminal of the capacitor C.

The present disclosure also provides a semiconductor chip, including a protected circuit and the above electro-static discharge protection circuit.

In the specification, the description of terms such as “some embodiments”, “other embodiments”, “desirable embodiments” and the like means that a specific feature, structure, material or characteristic described in combination with the embodiment(s) or example(s) are included in at least one embodiment or example of the present application. In this specification, the schematic description of the above terms does not necessarily refer to the same embodiment or example.

The technical characteristics of the above embodiments can be employed in arbitrary combinations. In an effort to provide a concise description of these embodiments, not all possible combinations of all technical characteristics of the embodiments are described; however, these combinations of technical characteristics should be construed as disclosed in the description as long as no contradiction occurs.

The above embodiments are intended to illustrate several implementations of the present application in detail, and they should not be construed as a limitation to the patentable scope of the present application. It should be noted that those of ordinary skill in the art can further make variations and improvements without departing from the concept of the present application. These variations and improvements all fall within the protection scope of the present application. Therefore, the protection scope of the present application should be subject to the protection scope defined by the claims.

1. An electro-static discharge protection circuit, comprising:
a silicon-controlled rectifier, comprising an anode, a cathode and an electro-static discharge path;
a detection unit, connected between the anode and the cathode of the silicon-controlled rectifier, and configured to generate a high level in response to static electricity occurring in a protected chip; and
a switching unit, connected to the electro-static discharge path, comprising an input terminal connected to an output terminal of the detection unit, and configured to turn on the electro-static discharge path based on the high level to discharge an electro-static discharge current.

2. The electro-static discharge protection circuit according to claim 1, wherein the electro-static discharge path comprises a first triode, a second triode, a first resistor and a second resistor; the first triode comprises an emitter serving as the anode of the silicon-controlled rectifier, a base connected to one terminal of the first resistor and a collector of the second triode, and a collector connected to one terminal of the second resistor and a base of the second triode; the other terminal of the second resistor is connected to the other terminal of the first resistor; and an emitter of the second triode serves as the cathode of the silicon-controlled rectifier.

3. The electro-static discharge protection circuit according to claim 2, wherein the first triode is a PNP triode, and the second triode is an NPN triode.

4. The electro-static discharge protection circuit according to claim 2, wherein the silicon-controlled rectifier further comprises an electro-static discharge trigger path; the electro-static discharge trigger path comprises a first diode and a second diode; the first diode comprises a cathode connected to the cathode of the silicon-controlled rectifier, and an anode connected to a cathode of the second diode; and an anode of the second diode is connected to the anode of the silicon-controlled rectifier.

5. The electro-static discharge protection circuit according to claim 4, wherein the silicon-controlled rectifier comprises:
a substrate, wherein a fourth well region, a first well region and a second well region are formed in the substrate; a first doped region and a second doped region are formed in the first well region; a third doped region and a fourth doped region are formed in the second well region; a fifth doped region is further formed in the substrate; the second doped region is connected to a cathode and formed into the cathode of the silicon-controlled rectifier; and the third doped region is connected to an anode and formed into the anode of the silicon-controlled rectifier;
the third doped region, the second well region and the first well region are equivalent to the first triode; and the second doped region, the first well region and the second well region are equivalent to the second triode; and
the first doped region and the second doped region are equivalent to the first diode; and the third doped region and the fourth doped region are equivalent to the second diode.

6. The electro-static discharge protection circuit according to claim 5, wherein a third deep well region is further formed in the substrate; and the third deep well region is provided on a lower surface of the first well region and a part of a lower surface of each of the fourth well region and the second well region.

7. The electro-static discharge protection circuit according to claim 3, wherein the detection unit comprises a third resistor and a capacitor; the capacitor comprises one terminal connected to the anode of the silicon-controlled rectifier, and the other terminal connected to one terminal of the third resistor and serving as the output terminal of the detection unit; and the other terminal of the third resistor is connected to the cathode of the silicon-controlled rectifier.

8. The electro-static discharge protection circuit according to claim 7, wherein the switching unit comprises an N-channel metal-oxide semiconductor transistor; and the N-channel metal-oxide semiconductor transistor comprises a gate serving as an input terminal and connected to the output terminal of the detection unit, a source connected to one terminal of the second resistor, the collector of the first triode and the base of the second triode, and a drain connected to one terminal of the first resistor, the base of the first triode and the collector of the second triode.

9. A chip, comprising a protected circuit and the electro-static discharge protection circuit according to claim 1.

10. A semiconductor device, comprising:
a substrate, comprising a first well region with a first conductivity type, and a second well region with a second conductivity type, wherein the first well region is in contact with the second well region, and a PN junction is formed on a contact surface;
a first doped region with the first conductivity type and a second doped region with the second conductivity type are provided in the first well region; and
a third doped region with the first conductivity type and a fourth doped region with the second conductivity type are provided in the second well region;
wherein the second doped region is spaced from the second well region, and the third doped region is spaced from the first well region.

11. The semiconductor device according to claim 10, wherein the substrate is the first conductivity type, and the substrate comprises a third deep well region in at least partial contact with the first well region, the third deep well region is a second conductivity type.

12. The semiconductor device according to claim 11, wherein the substrate comprises a fourth well region in contact with the first well region, and the fourth well region is the second conductivity type.

13. The semiconductor device according to claim 12, wherein the substrate comprises a fifth doped region arranged outside the first well region, the second well region, the third deep well region and the fourth well region, and the fifth doped region is the first conductivity type.

14. An electro-static discharge protection circuit, comprising the semiconductor device according to claim 10, a detection unit and a switching unit;
the third doping region of the semiconductor device is connected with a first conductive terminal of a protected circuit, and the second doping region is connected with a second conductive terminal of the protected circuit;
the detection unit is coupled between the first conductive terminal and the second conductive terminal, and is configured to control the switching unit to turn on when the first conductive terminal receives an electrostatic pulse, and to control the switching unit to turn off after a predetermined time;
one terminal of the switching unit is connected with the first doping region, and the other terminal of the switching unit is connected with the fourth doping region; the switching unit is configured to electrically connect the first doped region with the fourth doped region when it is turned on, and disconnect the first doped region from the fourth doped region when it is turned off.

15. The electro-static discharge protection circuit according to claim 14, wherein the detection unit comprises a third resistor and a capacitor, one terminal of the third resistor is connected with the second conductive terminal, the other terminal of the third resistor is connected with a first terminal of the capacitor, and a second terminal of the capacitor is connected with the fourth doped region.

16. The electro-static discharge protection circuit according to claim 15, wherein the switching unit is a switching transistor, and a control terminal of the switching transistor is connected with the first terminal of the capacitor.

17. The electro-static discharge protection circuit according to claim 16, wherein the first conductive type is P-type, and the second conductive type is N-type.

18. The electro-static discharge protection circuit according to claim 17, wherein the switching transistor is an N-channel metal-oxide semiconductor (NMOS) transistor, a gate of the NMOS transistor is connected with the first terminal of the capacitor, a drain of the NMOS transistor is connected with the fourth doped region, and a source of the NMOS transistor is connected with the first doped region.

19. A semiconductor chip, comprising a protected circuit and the electro-static discharge protection circuit according to claim 14.
